(19) United States
(12) Patent Application Publication
(10) Pub. No.: US 2026/0059701 A1
(43) Pub. Date: Feb. 26, 2026

(54) NODE ISOLATION DEVICES, SYSTEMS AND METHODS

(71) Applicant: CoolIT Systems, Inc., Calgary (CA)

(72) Inventors: Marek Serwin, Calgary (CA); Mohammad Reza Najjari, Calgary (CA)

(21) Appl. No.: 19/253,991

(22) Filed: Jun. 30, 2025

Related U.S. Application Data
(60) Provisional application No. 63/666,646, filed on Jul. 1, 2024.

(51) Int. Cl. H05K 7/20; F16K 31/06; F16L 37/00

(52) U.S. Cl. CPC H05K 7/20272; F16K 31/0668; F16L 37/002; F16L 2201/20

(57) ABSTRACT

An electro-mechanical actuator for a valve can have a collar configured to envelope a portion of a commercially available liquid coupler. The collar can engage a region of the liquid coupler and a bias member can urge the collar to displace a movable member of the liquid coupler and thereby to break a coupling. A dowel can retain the collar against the force applied by the bias member and a tension member can, under threshold tension, retract the dowel, releasing the collar to move under influence of the bias member. Other valves have a gate element coupled with an armature to rotate the gate element under an electromagnetic field. The gate element can define a recess and a retainer can reside in the recess. As the gate element rotates, the retainer can align with a longitudinal segment of the recess and allow the gate element to displace longitudinally.

### CROSS-REFERENCE TO PERTINENT APPLICATIONS

This application claims benefit of and priority to U.S. patent application Ser. No. 63/666,646, filed Jul. 1, 2024, the contents of which are hereby incorporated by reference in their entirety as fully as if recited in fully herein, for all purposes.

This application also pertains to concepts disclosed in co-pending U.S. patent application Ser. No. 18/217,729, filed Jul. 3, 2023. Other pertinent disclosures include U.S. patent application Ser. No. 16/525,303, filed Jul. 29, 2019, which claims benefit of and priority to, as a continuation of, co-pending U.S. patent application Ser. No. 15/354,982, filed Nov. 17, 2016, issued as U.S. Pat. No. 10,365,667 on Jul. 30, 2019, which claims benefit of and priority to U.S. patent application Ser. No. 62/256,519, filed Nov. 17, 2015, and claims benefit of and priority to, as a continuation-in-part of, co-pending U.S. patent application Ser. No. 14/777,510, filed Sep. 15, 2015, issued as U.S. Pat. No. 10,364,809 on Jul. 30, 2019, which is a U.S.

National Phase Application of International Patent Application No. PCT/IB2014/059768, filed Mar. 14, 2014, which claims benefit of and priority to U.S. patent application Ser. No. 61/793,479, filed Mar. 15, 2013, U.S. patent application Ser. No. 61/805,418, filed Mar. 26, 2013, U.S. patent application Ser. No. 61/856,566, filed Jul. 19, 2013, and U.S. patent application Ser. No. 61/880,081, filed Sep. 19, 2013, as well as U.S. patent application Ser. No. 61/522,247, filed Aug. 11, 2011, U.S. patent application Ser. No. 61/622,982, filed Apr. 11, 2012, U.S. patent application Ser. No. 61/794,698, filed Mar. 15, 2013, U.S. patent application Ser. No. 13/559,340, filed Jul. 26, 2012, now U.S. Pat. No. 9,496,200, U.S. patent application Ser. No. 61/908,043, filed Nov. 23, 2013, and U.S. patent application Ser. No. 14/550,952, filed Nov. 22, 2014.

Each foregoing patent and patent application is hereby incorporated by reference in its entirety as if fully set forth herein, for all purposes.

### FIELD

This application and the subject matter disclosed herein (collectively referred to as the “disclosure”), generally concern control of fluid-flow paths in heat-transfer systems, and more particularly, but not exclusively, to electro-mechanically actuated flow-path controllers, with automatically decouplable couplers and electro-mechanically actuated valves being but two specific examples of disclosed flow-path controllers. More particularly, but not exclusively, this disclosure pertains to systems, methods, and components to interrupt a flow of a working fluid when a leak or other undesirable condition has been detected. As but one illustrative example, an actuator can manipulate a so-called quick-release coupling to automatically interrupt a flow of coolant to a server when a leak has been detected.

### BACKGROUND INFORMATION

New generations of electronic components, such as, for example, memory components, microprocessors, graphics processors, application specific integrated circuits (ASICs), hard drives, and power electronics semiconductor devices, produce increasing amounts of heat when operating. In addition, electronic devices, such as, for example, servers, computers, game consoles, power electronics, communications and other networking devices, batteries, and so on, arrange electronic components in close proximity with each other. If the heat generated by operating such components is not removed from such devices at a sufficient rate, the components can overheat, decreasing their performance, reliability, or both, and in some cases such overheating can result in outright component damage or failure.

The prior art has addressed these challenges using air cooling, liquid cooling (e.g., involving liquid coolant, e.g., water, glycol, polyethylene glycol, etc.), or a combination thereof, to transfer and dissipate heat from electronic components to an ultimate heat sink, e.g., the atmosphere.

Conventional air cooling relies on natural convection or uses forced convection (e.g., a fan mounted near a heat producing component) to replace heated air with cooler ambient air around the component. Such air-cooling techniques can be supplemented with a conventional “heat sink,” which often is a plate of a thermally conductive material (e.g., aluminum or copper) placed in thermal contact with the heat-producing component. The heat sink can spread heat from the component to a larger area for dissipating heat to the surrounding air. Some heat sinks include “fins” to further increase the surface area available for heat transfer and thereby to improve the transfer of heat to the air. Some heat sinks include a fan to force air among the fins and are commonly referred to in the art as “active”heat sinks.

Liquid cooling improves cooling performance compared to air cooling techniques described above, as many liquids, e.g., water, have significantly better heat transfer capabilities than air. FIG. 1 illustrates various components of a liquid cooling loop 100. The cooling loop 100 typically operates by (1) transferring heat, Q in, from a heat-generating electronic component (not shown) to a cool liquid passing through a heat exchanger 110 (sometimes referred to in the art as a “cold plate” or a “heat sink”) placed in thermal contact with the heat-generating component, (2) transporting the heat absorbed by the liquid (which may remain a sub-cooled liquid or may become during the heating a saturated mixture of liquid-and gas-phase, or may be entirely in a gas-phase) to a remote radiator 120, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) rejecting the heat, Q'out, from the heated liquid (which may enter in a liquid-phase, a gas-phase, or a mixture thereof) with a remote radiator to another medium (e.g., air or facility water passing through the remote radiator), and (4) returning cooled liquid to the heat exchanger (or heat sink). Many heat exchangers for removing heat generated by such components have been proposed. As but one example, device-to-liquid heat exchangers have been proposed, as for example in U.S. Ser. No. 12/189,476 and related patent applications, and in other patent applications (e.g., U.S. patent application Ser. No. 63/635,593, filed Apr. 17, 2024, U.S. patent application Ser. No. 61/794,698, filed Mar. 15, 2013). Each of the foregoing disclosures is hereby incorporated by reference as fully as if recited herein in its entirety, for all purposes.

As indicated in FIG. 1, one or more conduits convey the fluid between and among the foregoing components. A fluid coupler couples each conduit with the corresponding components to facilitate movement of the fluid (e.g., in a liquid-phase) between the respective conduit and each corresponding component.

U.S. patent application Ser. No. 18/217,729, filed Jul. 3, 2023, its priority applications disclosed an electro-mechanical actuator can cause one or more valves to open or to close, or cause a pair of matingly engaged couplers that together define a liquid coupling between two components (sometimes referred to in the art as, for example, a “dripless quick-connect” or a “quick-disconnect”) to decouple from each other.

### SUMMARY

Disclosed principles and embodiments of them provide actuators suitable for controlling a flow of a liquid through a system or a segment thereof. In some respects, an electro-mechanical actuator can manipulate one or more features of a valve or a matingly engaged pair of couplers that interrupt or otherwise manipulate a flow of a liquid through the valve or the pair of couplers. For example, the actuator can receive a signal or other command from a controller. The controller can emit the signal or issue the command responsive to an input from a sensor that detects a change in condition of an observed operational parameter. For example, a sensor can detect a leak of coolant or a change (e.g., a loss) of pressure or any other observable or derived parameter indicative of an operating condition of a system containing a working fluid, e.g., a liquid-based cooling loop. Suitable sensors are known from Applicant's prior patent disclosures and elsewhere in the prior art.

In some respects, disclosed concepts pertain to actuators that can be retrofit to existing valves and fluid couplings to allow existing valves and fluid couplings to be automatically actuated despite being configured for manual actuation. In other respects, disclosed concepts pertain to improvements to existing valves and fluid couplings to allow them to be automatically actuated. Such improvements can eliminate features of some disclosed actuators, e.g., features used to make disclosed principles compatible with existing valves and fluid couplings. By eliminating such features, the combination of a disclosed actuator and a valve or fluid couplings can reduce the occupied volume of the device. Such reduced volume can provide an increase in packing density of automatically actuatable valves or fluid couplings compared to retrofitted valves or fluid couplings.

The foregoing and other features and advantages will become more apparent from the following detailed description, which proceeds with reference to the accompanying drawings.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 illustrates a closed liquid cooling loop.

FIG. 2 illustrates a pair of couplers of the type disclosed herein.

FIG. 3 is a photograph of a pair of complementary couplers.

FIG. 4 is a photograph of the pair of complementary couplers shown in FIG. 3 matingly engaged with each other to form a fluid coupling.

FIG. 5 illustrates a working embodiment of a cooling system having automatically decouplable couplers.

FIG. 6 shows a branch of fluid circuit of a heat transfer system.

FIG. 7 illustrates a cross-sectional view of an actuator configured to automatically decouple two pair of matingly engaged couplings of the type shown in FIGS. 2, 3 and 4. FIG. 7A depicts a cross-sectional view of another embodiment of such an actuator.

FIGS. 8, 9 and 10 show a sequence of frames from a video showing a working embodiment of an actuator automatically decoupling two pair of matingly engaged couplings as in FIG. 7.

FIG. 11 shows an exploded view illustrating several components of an actuator and coupler as in FIG. 7.

FIG. 12 shows an isometric view of an actuator as in FIG. 7.

FIG. 13 shows an X-ray image of a portion of an actuator as in FIG. 7.

FIG. 14 shows an isometric view of an electromechanically actuated valve.

FIG. 15 shows an isometric, cross-sectional view of an electromechanically actuated valve as in FIG. 14. In FIG. 15, the valve is “open”to permit liquid to pass through the valve.

FIG. 16 shows an isometric, cross-sectional view of the electromechanically actuated valve shown in FIG. 15. In FIG. 16, the valve is “closed” to prevent liquid from passing through the valve.

FIG. 17 shows an exploded isometric, cross-sectional view of the electromechanically actuated valve shown in FIGS. 15 and 16.

FIG. 18 shows an exploded isometric view of the moveable gate element and retainer sleeve from the valve embodiment shown in FIGS. 15, 16 and 17.

FIG. 19 shows an exploded isometric view of another embodiment of a moveable gate element suitable for use in a valve embodiment as in FIGS. 15, 16 and 17, together with a retainer sleeve.

FIG. 20 shows an isometric view of another embodiment of an electromechanically actuated valve.

FIG. 21 shows an isometric, cross-sectional view of the electromechanically actuated valve shown in FIG. 20 having a gate element in a “closed” position to prevent liquid from passing through the valve.

### DETAILED DESCRIPTION

The following describes various principles related to managing liquid flowing through a circuit or a segment thereof, and more particularly but not exclusively to interrupting the flow of liquid. For example, certain aspects of disclosed principles pertain to couplings between components and actuators suitable for decoupling such couplings automatically. That said, descriptions herein of specific apparatus configurations and combinations of method acts are but particular examples of contemplated systems chosen as being convenient illustrative examples of disclosed principles. One or more of the disclosed principles can be incorporated in various other systems to achieve any of a variety of corresponding system characteristics.

Thus, systems having attributes that are different from those specific examples discussed herein can embody one or more presently disclosed principles and can be used in applications not described herein in detail. Accordingly, such alternative embodiments also fall within the scope of this disclosure.

A liquid coupling between two components can including a first coupler and a second coupler that are complementarily configured with regard to each other. For example, one of a complementary pair of couplers can define a socket and the other one of the pair can define a stud. The socket can receive the stud in a mating arrangement. Moreover, one of the couplers can define, for example, one or more circumferentially extending grooves and the other one of the couplers can define a circumferentially extending catch configured to engage at least one of the one or more circumferentially extending grooves. For example, a retractable barb, shelf or other latch or a plurality of circumferentially balls, each being movable radially, can seat in selected one or more of the one or more circumferentially extending grooves to longitudinally retain complementary pair of couplers with each other. In some embodiments, a longitudinally movable collar

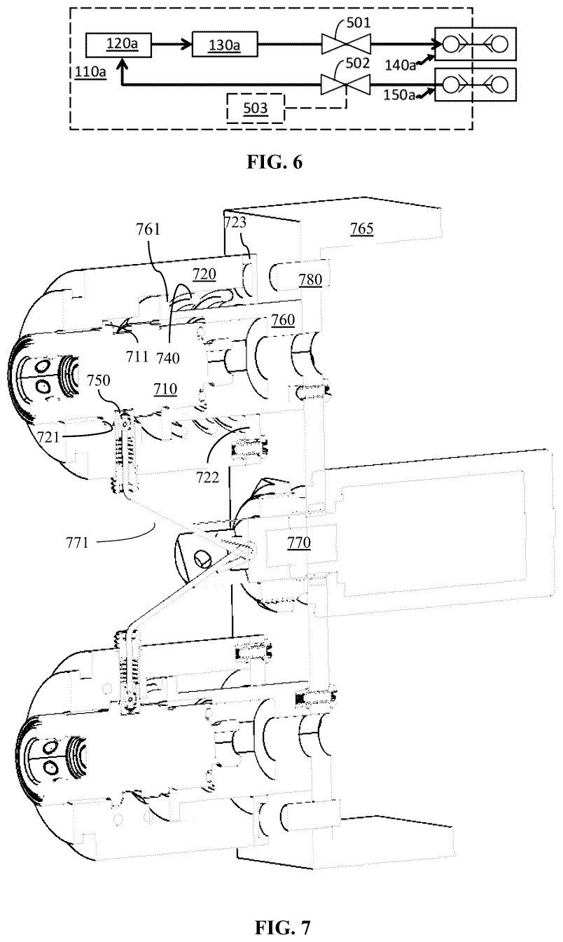

FIG. 2 shows a two-member coupling. The fluid coupling 400 has a first member (or coupler) 410 configured to matingly couple with and to decouple from a second member (or coupler) 420 to provide a decouplable coupling between a corresponding first fluid conduit 401 and a corresponding second fluid conduit 402. Such a coupling is depicted, for example, schematically at inlets 150a-n and outlets 140a-n in FIG. 6 in U.S. patent application Ser. No. 13/559,340. To inhibit a leak of fluid from the coupler 400 when coupling or decoupling the first and the second members 410, 420 to or from each other, one or both of the members 410, 420 can have an internal valve that automatically closes before, during or after the members 410,420 are decoupled from each other and automatically opens before, during or after the members are coupled to each other.

For example, a first member 410 can define an open interior bore 413 sized to receive a shank 422 extending from the second member 420. Either or both members 410, 420 can define an interior valve that opens after the bore 413 matingly and/or sealingly engages the shank 422. For example, an interior wall of the bore 413 can have a pliable gasket (e.g., an O-ring) extending circumferentially around the bore and positioned at a selected first depth within the bore. The gasket can be configured relative to the shank (e.g., a diameter thereof) to sealingly engage with an outer surface of the shank 422 as the shank slides into the bore 413 to a depth greater than the selected first depth. As the shank slides deeper into the bore, a portion within the bore 413 can urge against a portion of the shank to open either or both valves corresponding to the respective members 410, 420 and thereby to fluidically couple the first conduit 401 with the second conduit 402.

Such automatic actuation of the valves can result from a resiliently compressible member (e.g., a spring, not shown). For example, the valve can be closed in an “at-rest” position when urged by a corresponding resiliently compressible member. The coupling members 410, 420 can define correspondingly configured features that urge the valve open against the force applied by the resiliently compressible member as the members 410, 420 are brought into a mating engagement. With such an automatically actuatable valve, the coupler members 410, 420 can inhibit fluid leaks when coupling or decoupling the coupler members 410, 420.

As well, a compressive force applied between the members 410, 420 that actuates the valve by overcoming a force of a resilient member, as just described, can compress such a resilient member. The compressed resilient member can urge the members 410, 420 apart from each other when the compressive force is removed.

However, the coupler 400 can also have a retainer configured to retain the decouplable coupling between the first member 410 and the second member 420 against the outwardly applied force of the compressed resilient member. However, when a retention force applied by the retainer to the first and the second members 410, 420, the compressed resilient member can urge the first member 410 and the second member 420 apart with sufficient force as to cause the coupled members 410, 420 to decouple from each other and thereby to automatically close the respective valves.

The retainer depicted in FIG. 2 includes a cylindrical sleeve 414 overlying a body 412 of the first member 410, a plurality of bearings positioned at discrete circumferential positions relative to the bore 413, as well as a groove 424 positioned proximally of the shank 422 of the second member 420. When the first and the second members 410, 420 are matingly engaged with each other, the bearings 418 rest within the groove 424. The wall of the groove urges against the bearings when the mated first and the second members 410, 420 are urged together in compression or pulled apart in tension, and the sleeve 414 overlying the bearings prevents the bearings 418 from moving radially outward from the bore 413, locking the first and the second members 41, 420 together.

The sleeve 414 can slide longitudinally to and fro relative to the body 412 from a retention configuration, as shown in FIG. 2 to an engagement/disengagement configuration (not shown). In the engagement/disengagement configuration, the sleeve 414 longitudinally retracts from the depicted retention configuration until the sleeve urges against a shoulder 416 defined by the body 412. When the sleeve 414 is retracted, the bearings 418 can move radially outward relative to the bore 413, allowing the members 410, 420 to separate from each other as they are pulled apart.

The illustrated sleeve defines an outer surface and a circumferentially extending groove recessed from the outer surface. The groove facilitates gripping by a user's hand when retracting the sleeve 414 relative to the body 412. As well, the coupler member 410 includes a resilient member (e.g., a spring, not shown) configured to resiliently urge the sleeve 414 toward the retention configuration shown in FIG. 2. To retract the sleeve to the engagement/disengagement configuration, the force of the resilient spring and any friction as between the sleeve and the body 412 needs to be overcome. Once the sleeve is partially or fully retracted from the illustrated retention configuration, the resilient member urges the sleeve 414 toward the retention configuration. In many embodiments, the force applied to the sleeve by the resilient member sufficiently exceeds any frictional force between the sleeve 414 and the body 412 to allow the sleeve 414 to automatically return to the illustrated retention configuration. As described more fully below, the force applied to the sleeve 414 by the resilient member sufficiently exceeds such frictional forces as well as other forces, e.g., servo or other actuator resistance when the servo or other actuator is not actuated. The working embodiment shown in FIG. 5 includes automatically decouplable couplers similar in arrangement to the coupler 400 shown in FIG. 2 and described above.

The cooling system shown in FIG. 5 is similar to a cooling system disclosed, for example, in U.S. patent application Ser. No. 13/559,340, filed Jul. 26, 2012, and the applications from which the '340 Application claims priority, each of which patent applications is hereby incorporated by reference as if recited in full herein. For example, referring to FIG. 5, the distribution manifold 401b has several coupler members 410b configured to couple with corresponding coupler members 420b affixed to an inlet conduit 402b. At an end of the conduit 402b positioned opposite the coupler member 420b, the conduit is coupled to a cold plate to deliver coolant to the cold plate from the distribution manifold 410b. Similarly, the collection manifold 401a has several coupler members 410a configured to couple with corresponding coupler members 420a affixed to an outlet conduit 402a. At an end of the conduit 402a positioned opposite the coupler member 410a, the conduit 402a is coupled to a corresponding cold plate to receive heated coolant from the respective cold plate. The working embodiment has first and second cold plates, and the conduit 402b is coupled to the first cold plate and the conduit 402a is coupled to the second cold plate. In other embodiments, however, the conduits 402a, 402b are coupled to the same cold plate. Still other embodiments have more than two cold plates and the conduits 402a, 402b are coupled to respective cold plates and the remaining cold plates are coupled to the respective cold plates fluidically between the conduits 402a, 402b.

The working embodiment also includes an actuator shaft 430 mechanically coupled with the sleeves 414 of the coupler members 410a, 410b. Such mechanical coupling can be any form of coupling or linkage sufficient to permit the actuator shaft 430 to longitudinally slide the sleeves 414 to retract the sleeves from overlying the bearings and thereby to permit the coupler members 410a, 410b to decouple from each other.

As the white double-headed arrow indicates, the actuator shaft 430 can linearly translate generally perpendicularly to the manifolds 401a, 401b and generally parallel to a longitudinal axis of the coupler members 410a, 410b. As the actuator shaft 430 retracts toward the manifolds 401a, 401b with a force sufficient to overcome friction between the sleeves 414 and the corresponding bodies 412, as well as the force applied by the resilient member, the sleeves 414 of the respective coupler members 410a, 410b also retract, permitting the bearings 418 (FIG. 2) to move radially outward of the bore 413 (FIG. 2) and the shank 422 to eject from the bore, as shown in FIG. 5. In some embodiments, including in the working embodiment, the coupler members 410a, 410b separate automatically under the force of the resilient member that urges the valves closed when the retainer sleeve 414 retracts sufficiently to permit the bearings to move radially outward. In FIG. 5, the actuator shaft 430 has returned to an unactuated, extended position in which the sleeves 414 overlie the bearings 418, after the shaft 430 retracted the sleeves 414 to automatically eject the coupler members 420a, 420b.

In the embodiment shown in FIG. 5, the actuator shaft is mechanically coupled to two sleeves 414. In other embodiments, each activator shaft can be coupled to only one sleeve or more than two sleeves. For example, some servers can have more than one inlet conduit 402b and/or more than one outlet conduit 402a, and one actuator shaft can be configured to retract each sleeve 414 corresponding to all inlet and outlet conduits for a give server. In still other embodiments, one actuator shaft 430 is mechanically coupled to each of one or more inlet conduits for a given server and another actuator shaft is mechanically coupled to each of one or more outlet conduits for the given server.

A servo, a stepper-motor, or other electro-mechanical actuator (not shown) can urge the actuator shaft 430 or other linkage to translate in space from a first position to a second position. The first position can correspond to a retention configuration of a coupler of the type described herein and the second position can correspond to an engagement/disengagement configuration of the coupler (e.g., with the sleeve 414 retracted toward the shoulder 416). The servo or other actuator can be activated by a controller responsively to a change in an observed state of an operational parameter. For example, a controller can activate the servo or other actuator responsively to an alert or other command issued by a control system, or (e.g., with a latching control system) responsively to an absence of an alert or other command.

As but one example, the conduits 402a, 402b corresponding to a cooling system for a given server can be automatically disconnected from the manifolds 401a, 401b in response to a leak being detected within the given server, while all other servers in the rack can remain operational. For example, each server can have one or more corresponding leak sensors, e.g., of the type described herein, and each leak sensor can have a unique identifier (e.g., address). In some instances, including the working embodiment, the leak sensor is configured as a repositionable cable that can be positioned within a given server at one or more selected positions reasonably calculated by a user to be exposed to a cooling-system leak. Each leak sensor can be coupled to a controller configured to interpret an output signal from the leak (or other) sensor. The controller can have a look up table or other reference for establishing correspondence between each of several leak (or other) sensors and the server in or on which each leak sensor is positioned.

As well, each actuator shaft 430 (or corresponding actuator) can have a unique identifier, and another look up table or other reference can establish correspondence between each of several actuators and one or more servers. Accordingly, when the control system detects a leak (or other change of state) in a given server, the control system can identify the given server (or location in a given server), issue an alert identifying which one or more selected actuators should be activated, e.g., to automatically decouple the conduits 402a, 402b from the manifolds 401a, 401b to prevent further leaking within the affected server. The controller can further activate the one or more identified actuators and thereby urge the actuator shaft 430 (or other actuator member) through a range of motion contemplated to remove a retention force applied to the coupling 400, as by retracting the sleeves 414. Other detected changes of state can also actuate an actuator, e.g., to allow an automatic disconnection from the manifolds. Such a change in state can include, for example, a detected coolant temperature above or below a selected threshold temperature, a detected power failure, an observed pressure exceeding an upper threshold pressure, etc.

In the working embodiment depicted in FIG. 5, the actuator shaft 430 extends from a two-position linear actuator. The linear actuator (not shown) retracts when supplied with power and thereby urges the sleeves 414 toward the engagement/disengagement configuration when activated. When not activated, the linear actuator applies little or no longitudinal load to the sleeves, allowing the sleeves to resiliently return to the retention configuration (e.g., as under forces applied by springs within the first member 410 (FIG. 2) configured to urge the sleeve 414 toward the retention configuration shown in FIG. 2. In other embodiments, the linear actuator can urge the actuator shaft 430 away from the actuator when supplied with power.

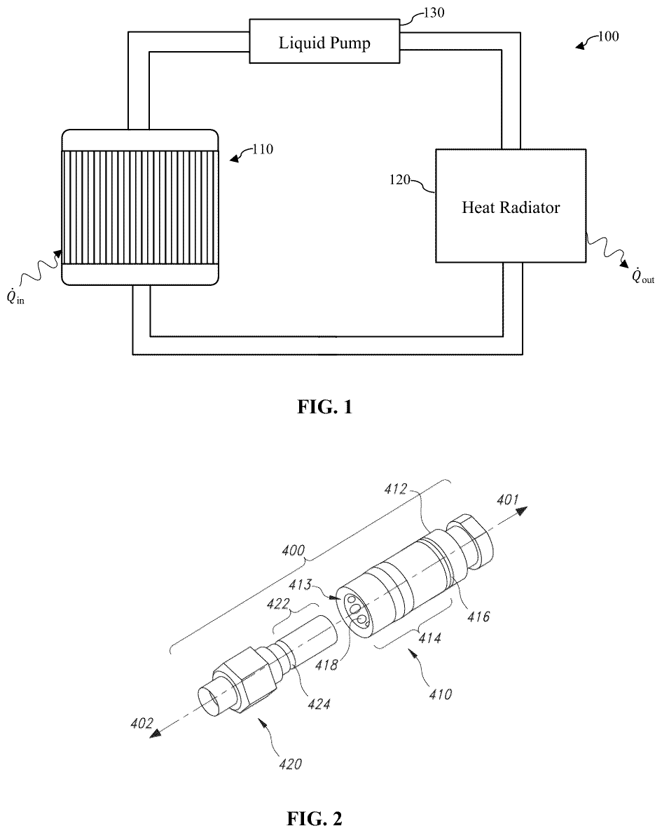

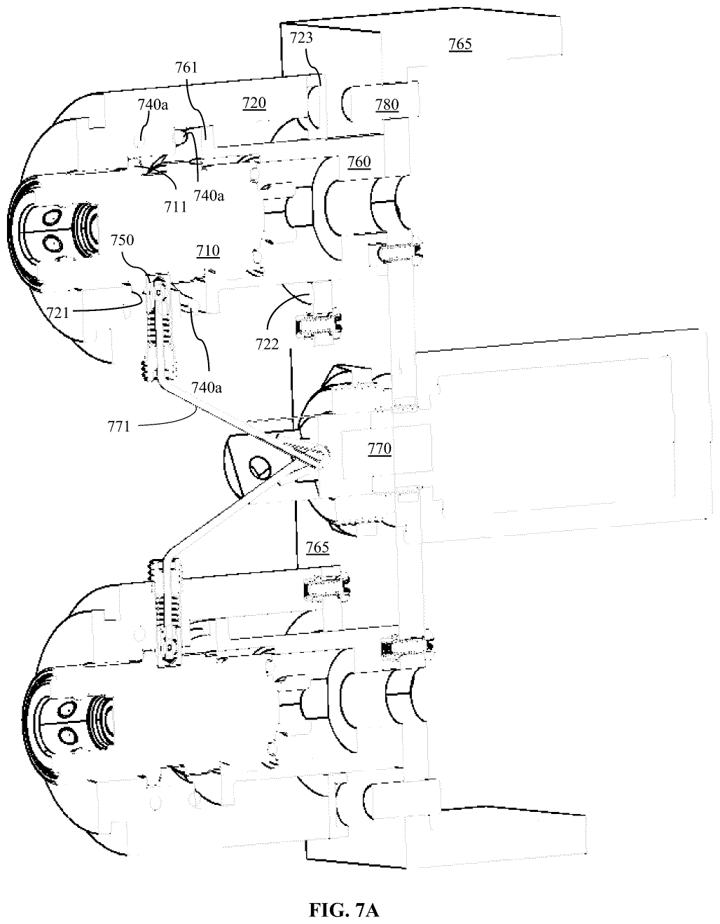

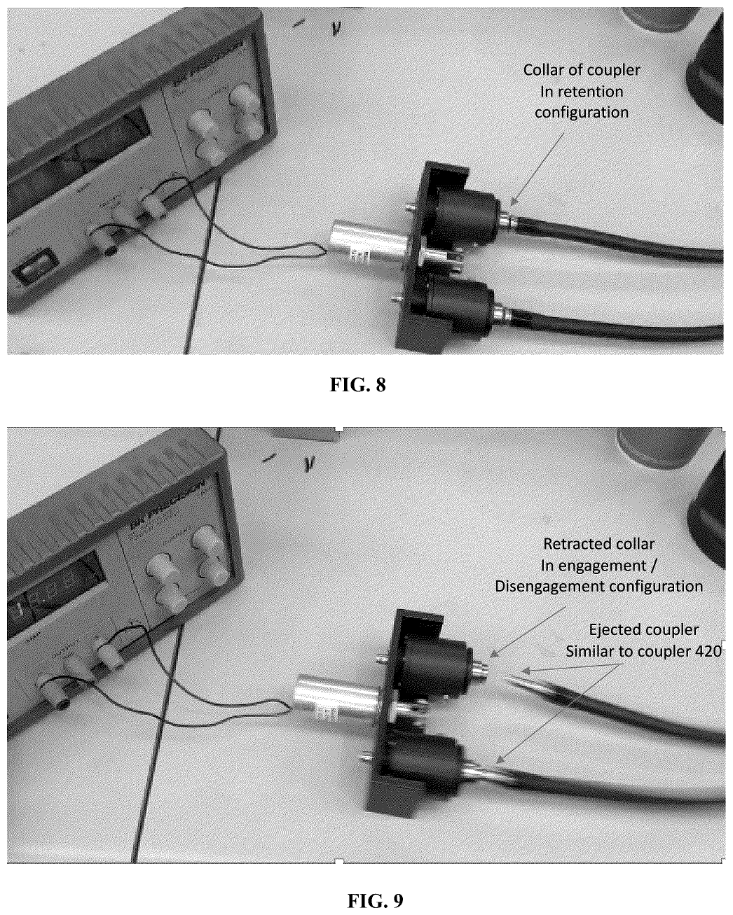

Turning now to FIG. 7, another actuator configured to automatically break a fluid connection (or to decouple a coupling) will be described. FIG. 7 shows an actuator suitable for contemporaneously withdrawing the collars of two couplers 710 similar, each coupler 710 being similar to the coupler 410 shown in and described in relation to FIG. 2. Although the actuator depicted in FIG. 7 is configured to withdraw the collars of two couplers 710, other actuator configurations can be configured to withdraw the collar of a single coupler 710 or more than two couplers 710. The working embodiment shown in FIG. 8 is in a retention configuration as shown in FIG. 7. On withdrawing the collars, a coupler, not shown in FIG. 7 but similar to the coupler 420 shown in and described in relation to FIG. 2, can eject from the illustrated couplers 710 under an internal biasing force, generally as described above in connection with FIGS. 1 to 6, above. The sequence of images in FIGS. 8, 9 and 10 depicts such ejection following withdrawal of the collars.

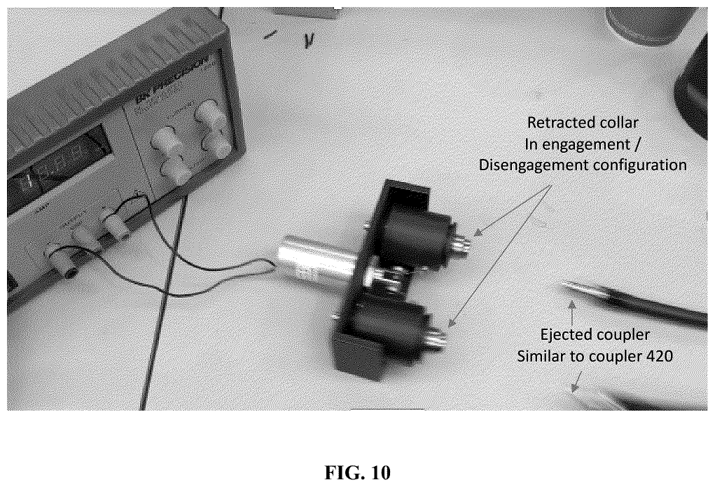

FIG. 7 shows a circumferentially extending ridge 711 defined by the retractable collar of each female coupler 710. As the collar retracts, i.e., shifts to the right in FIG. 7, the bearings positioned at discrete circumferential positions relative to the bore of the coupler 710 are released and can shift radially outward to release the otherwise retained stud of the other coupler (not shown in FIG. 7, but similar to the coupler 420). The actuator has an outer collar 720 that defines an internal shoulder 721 positioned opposite the ridge 711 such that as the outer collar 720 shifts longitudinally relative to the coupler 710, the internal shoulder 721 urges in a longitudinal direction against the ridge 711. If the longitudinal force applied by the shoulder 721 against the ridge 711 is sufficient to overcome static friction and any retaining force (e.g., from an internal biasing member), the collar (or sleeve) of the coupler 710 can move, e.g., shift or slide longitudinally (e.g., to the right in FIG. 7) from the retention configuration shown in FIGS. 7 and 8 into an engagement/disengagement configuration, e.g., as shown in FIGS. 9 and 10.

In FIG. 7, an actuator biasing member, e.g., a spring 740 (“strong spring”), can tend to urge the outer collar 720 longitudinally relative to the coupler 710 such that the outer collar urges against the ridge 711 and thereby urges the collar of the coupler 710 toward the engagement/disengagement configuration. However, as FIG. 7 shows, a movable pin 750 can extend transversely through the outer collar 720 and into a recess defined by, for example, a main body of the coupler 710, inhibiting or preventing relative longitudinal movement between the outer collar 720 and a portion of the coupler 710, and thereby inhibiting or preventing the actuator biasing member from causing the collar of the coupler 710 from moving into the engagement/disengagement configuration. Thus, the movable pin 750 can cause the coupler 710 to retain another coupler (not shown in FIG. 7) and thus maintain a fluid coupling between fluidically connected components.

However, on withdrawal of the pin 750 from the locking engagement shown in FIG. 7, e.g., on withdrawal of the pin from the recess defined by the coupler 710, the actuator biasing member, e.g., spring 740, can urge the outer collar 720 to move in a longitudinal direction (e.g., to the right in FIG. 7), which in turn causes the shoulder 721 of the outer collar 720 to urge against the ridge 711 and to thus move the collar of the coupler 710 to move from the retention configuration shown to an engagement/disengagement configuration. As the coupler 710 shifts to the engagement/disengagement configuration, the mating coupler (not shown in FIG. 7) can automatically eject from the coupler 710, thus fluidically decoupling the couplers from each other. The sequence of images in FIGS. 8, 9 and 10 depict a similar decoupling.

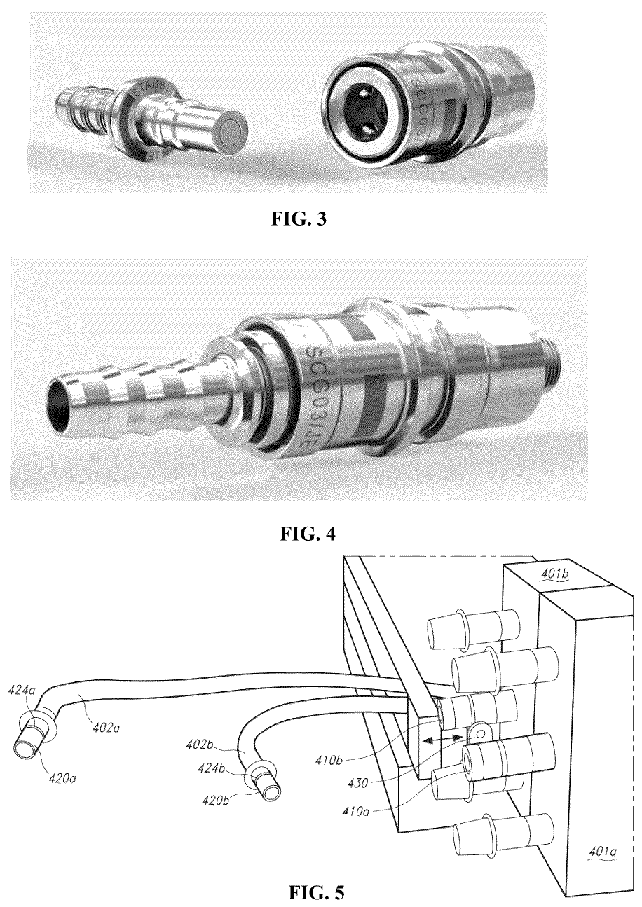

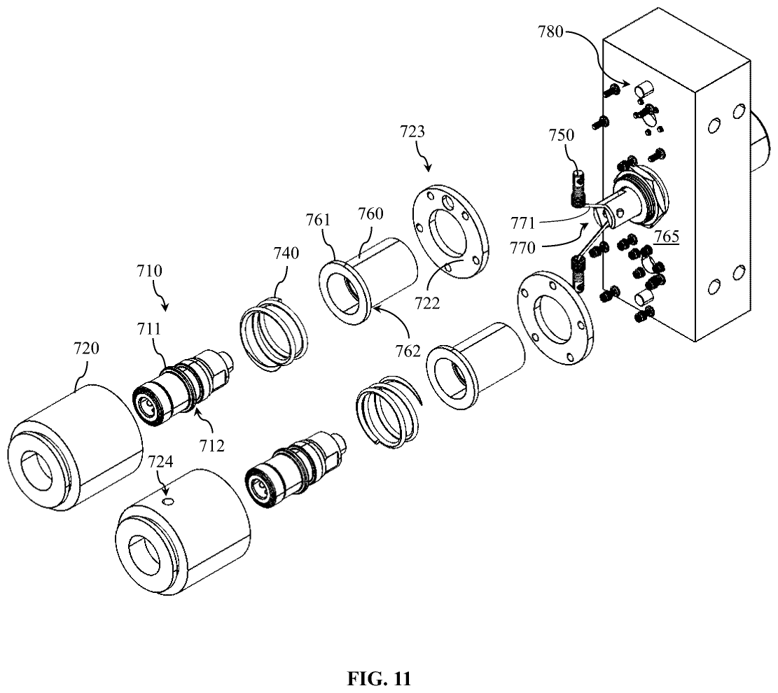

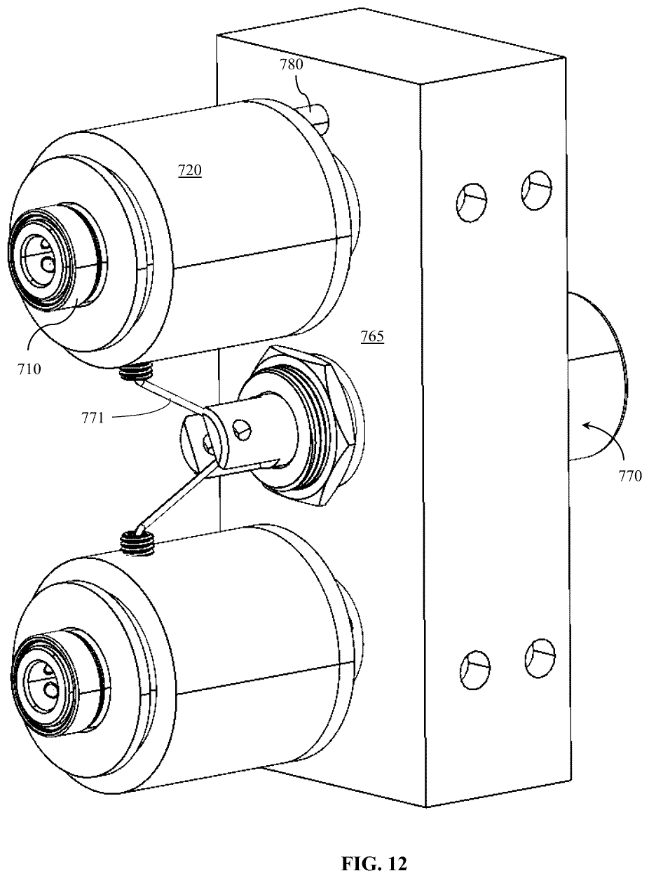

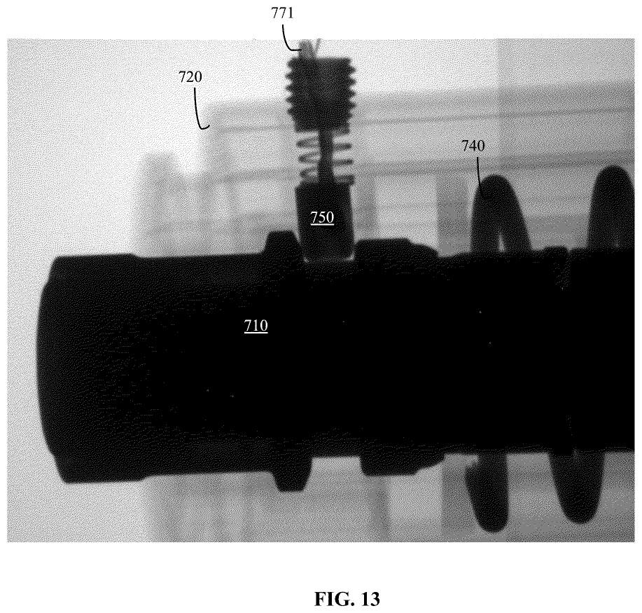

In FIG. 7, the resilient biasing member, e.g., a coil spring 740, is depicted in a compressed state between opposed end walls and within an annular gap positioned between an inner wall of the outer collar 720 and an outer wall of a chassis stud 760, or boss, or other fixed-position structure. As shown in FIG. 7, the chassis stud 760 extends transversely from a chassis 765. A proximal end of the illustrated chassis stud 760 is fixedly attached to a wall of the chassis 765 and defines a stepped inner bore that extends longitudinally from the proximal end of the chassis stud 760 to a distal end thereof. A distal region of the stepped inner bore receives a proximal portion of the coupler 710 in a longitudinally supporting arrangement, e.g., as shown in FIG. 7. A distal region of the chassis stud 760 defines a flange that extends radially outward of the distal end of the chassis stud. A distal region of the resilient biasing member, e.g., a coil spring 740, is positioned proximally of the distal flange of the chassis stud 760. A proximal end of the outer collar 720 is shown in FIG. 7 positioned proximally of the proximal end of the resilient biasing member, e.g., a coil spring 740, capturing the biasing member between the proximal end of the outer collar 720 and a distal end of the chassis stud 760. As noted, the chassis stud has a fixed position in this embodiment. The flange 761 at the distal end of the chassis stud 760 provides a bearing surface 762 against which the compressed biasing member 740 can urge. The internal flange 722 of the outer collar 720 (defined by the washer 723 shown in FIG. 11) provides a movable bearing surface against which the compressed biasing member 740 can urge. However, so long as the retainer pin 750 is positioned in the recess 712 defined by the wall of the coupler 710, the outer collar 720 and thus the shoulder 721 and the internal flange 722 thereof also are immovable. In FIG. 13, a retainer pin is shown seated in a circumferential groove defined by a female coupler similar to the female coupler shown in FIG. 3.

The internal flange 722 of the outer collar 720 (defined by the washer 723 shown in FIG. 11) is shown spaced from the wall of the chassis 765 to which the chassis stud 760 is attached. Thus, on removal of the pin 750 from the recess 712 in the coupler 710, the outer collar 720, under the longitudinal force applied by the compressed, resilient biasing member 740 to the flange 722, translates longitudinally in a proximal direction toward the wall of the chassis 765, bringing with it the sleeve of the coupler 710 as the shoulder 721 of the collar urges against the ridge 711. Again, as the sleeve of the coupler 710 translates proximally, the detent features of the coupler 710 are released, allowing the other coupler to eject from the coupler 710 (e.g., as in FIGS. 8, 9 and 10).

Automatic withdrawal of the pin 750 by a linear actuator 770 is now described. As FIG. 7 shows, the pin 750 can be positioned at a distal end of a pull wire 771 or other tether whose proximal end is physically coupled with a linear actuator 770. As noted above, a transverse bore 724 extends through a sidewall of the outer collar 720. When the outer collar 720 is positioned in a retention configuration (e.g., as shown in FIG. 7), the transverse bore through the outer collar 720 can align, e.g., radially, with the recessed region 712 of the coupler 710. In FIG. 7, the recessed region 712 of the coupler 710 is a circumferential groove. Once the transverse bore 724 through the outer collar 720 aligns with the recessed region 712 of the coupler 710, the pin 750 can be inserted within the recessed region of the coupler 710 and the outer collar 720 can be released by the user. As the outer collar 720 retracts proximally under force of the biasing member, the pin 750 can be locked in the recessed region 712 defined by the coupler 710. To ensure that the pin 750 seats within the recessed region 712 before the user releases the outer collar 720, a longitudinally extensible biasing member 751 (e.g., a compressed coil spring, “weak spring”) can be captured between the pin 750 and, for example, a set screw or other feature of the outer collar 720.

In FIG. 7, the pull wire 771 extends through the set screw and through the longitudinally extensible biasing member 751 to a distal end captured by the pin 750. A proximal end of the illustrated pull wire 771 is secured to the linear actuator 770. As the linear actuator 770 retracts in a longitudinal direction toward the chassis 765, the pull wire 771 withdraws the pin 750 from the recessed region 712 defined by the coupler 710. Once the distal end of the withdrawing pin 750 clears an outermost surface of the recess (e.g., the distal flange of the circumferential groove defined by the ridge 711 of the coupler 710), the outer collar 720 becomes free to translate longitudinally toward the chassis 765, which, as described above, retracts the collar of the coupler 710 and allows the internal biasing member(s) of the coupler 710 and the coupler mated therewith (not shown in FIG. 7) to eject from the coupler 710, e.g., as depicted in the sequence of images in FIGS. 8, 9, and 10.

As shown in FIG. 7, a proximity sensor 780 positioned proximally of the outer collar 720 can detect when the outer collar has translated to a proximal position that corresponds with the engagement/disengagement configuration of the coupler 710. Such a proximity sensor 780 can provide a confirmation signal to a controller to confirm that the actuator has caused the intended decoupling of the coupler 710 from the mated coupler.

For example, a controller can emit a control signal responsive to a detected condition (e.g., a detected leak). The control signal can cause the linear actuator to retract from the position shown in FIG. 7 and FIG. 8 to a release position as shown in FIGS. 9 and 10. In the release position, the pull wire 771 has been pulled and the pin 750 has thus been withdrawn from the recessed region 712 defined by the coupler 710, allowing the outer collar 720 to shift proximally, which in turn causes the coupler 710's sleeve to retract, which causes the coupler 710 to eject the mated coupler. Once the proximity sensor 780 detects the outer collar 720 has retracted, it can send a signal to the controller confirming this position. The controller can then issue a signal or other communication to, e.g., a gateway or a building management system or other control system to alert an operator to the broken fluid coupling caused by the decoupled couplers. This can allow the operator to take remedial action as well as allow a load controller to shift computing loads from the affected server(s) to another server having an operable cooling system. Once an operator performs appropriate maintenance, a complementary coupler can be inserted into the coupler 710 and the operator can manually translate the outer collar 720 in a distal direction (FIG. 7) until the pin 750 seats in the recessed region 712. The biasing member (“weak spring”) can urge the pin 750 to seat in the recessed region 712 once the recess and the pin 750 are in alignment.

Referring again to FIG. 6 in U.S. patent application Ser. No. 13/559,340, an actuator as just described can be operably coupled to, for example, the inlet couplers 150a-n and/or the outlet couplers 140a-n. One or more leak detectors, flow rate sensors, and/or other sensors can be suitably arranged relative to each heat-transfer element 110a-n and corresponding operable devices that might be damaged from, for example, exposure to a leaked coolant or other working fluid. A controller as described herein can issue an alarm or a command to which the actuator can respond by urging, for example, the respective sleeves (or collars) 414 toward the engagement/disengagement configuration. When the sleeve is sufficiently retracted, the compressive force applied to an internally positioned resilient member can be removed, causing the matingly engaged members 410, 420 to urge apart from each other as the resilient member returns to an uncompressed arrangement. An internal valve in each respective member 410, 420 can close to prevent leakage of a working fluid from the flow passages corresponding to the members 410, 420, thereby isolating the respective heat-transfer element(s) 110a-n from the remainder of the fluid circuit positioned among the various servers. Once a given branch of a heat-transfer system's fluid circuit has been isolated as just described, the corresponding equipment can be removed, inspected, and repaired without disrupting operation of adjacent equipment.

Any actuator suitable to retract one or more sleeves (or collars) 414 can be used. Examples of suitable actuators include linear motors, linear servos, ball-screws coupled with a rotary motor or servo, four-bar linkages, among other types of linear actuators configured to urge the actuator shaft 430 through a range of motion sufficient to retract one or more sleeves 414.

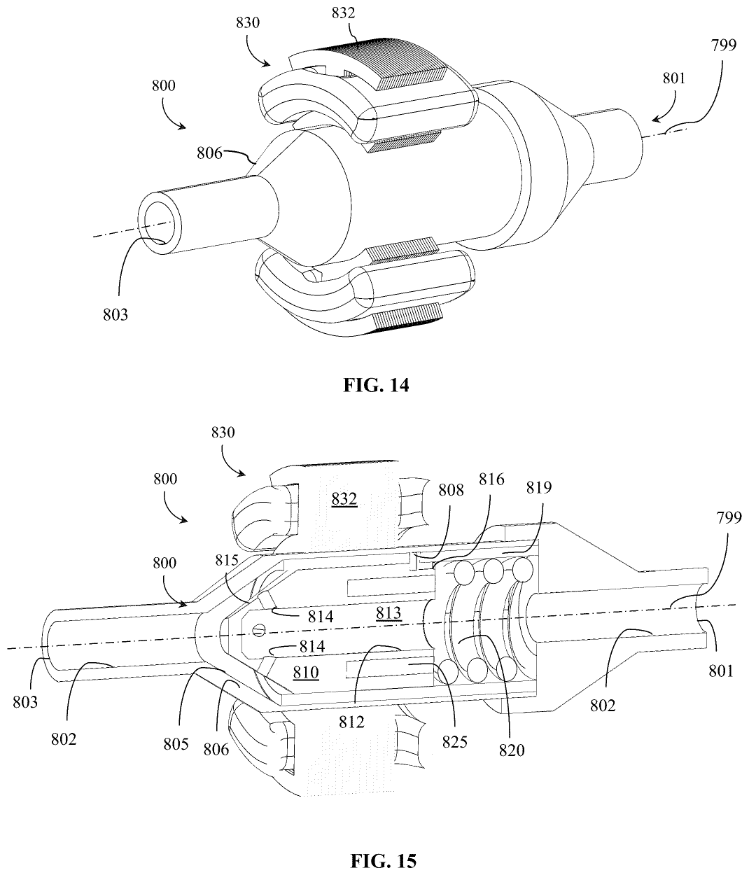

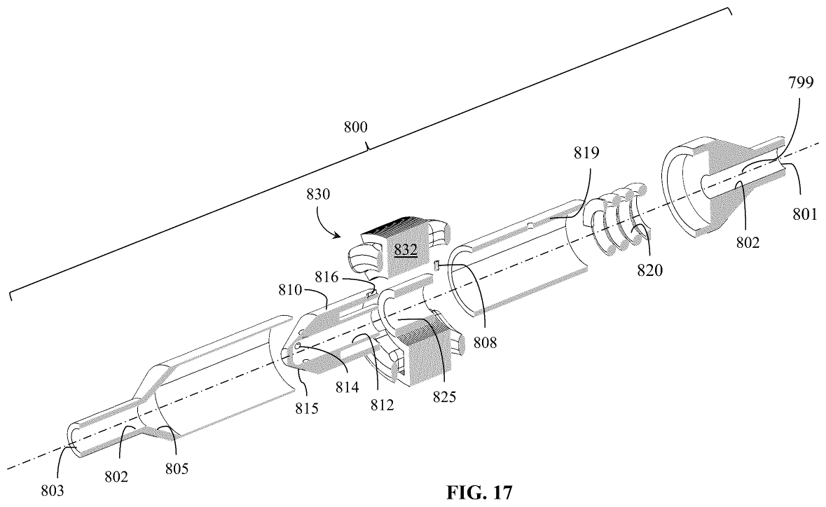

Other arrangements of actuators and couplers are possible. For example, the couplers described thus far are couplable and decouplable by sliding the sleeve 414 in a longitudinal direction, e.g., through actuation of the outer collar 720. However, some couplers are configured to decouple only after a member (e.g., a sleeve in some embodiments or a plunger in other embodiments, e.g., as with embodiments shown and described in FIGS. 14-21) rotates through a selected angle. In such an embodiment, a rotational actuator, stepper motor, or servo can be coupled (e.g., directly or magnetically) to the rotatable member to cause the rotatable member to rotate and thus automatically decouple the coupler. In still other embodiments, the coupler can require a combination of linear and rotational movement to automatically decouple the coupler. In such an embodiment, a two-degree-of-freedom actuator (e.g., an actuator or combination of actuators configured to urge a member in rotation and in linear translation) can be coupled to the coupler to automatically decouple the coupler.

Referring now to FIG. 14, other actuators and valves configured to automatically break a fluid connection (or to decouple a coupling) will be described. Actuators and valves described in connection with FIGS. 14 to 21 can be used as an alternative to couplings described in connection with and shown among FIGS. 7 to 13 to terminate a flow of liquid. As well or alternatively, actuators and valves described in connection with FIGS. 14 to 21 can be used in a conduit alone or in combination with so-called clean break blind mate connectors that provide a blindly matable fluid coupling between components (e.g., between a branch of a coolant loop within a server tray and manifolds for collecting and distributing coolant among a plurality of such branches or between a removable pump tray and a reservoir-and-pump unit as described in U.S. Pat. No. 11,395,443, issued Jul. 19, 2022, the contents of which are hereby incorporated in their entirety as if reproduced herein in full, for all purposes).

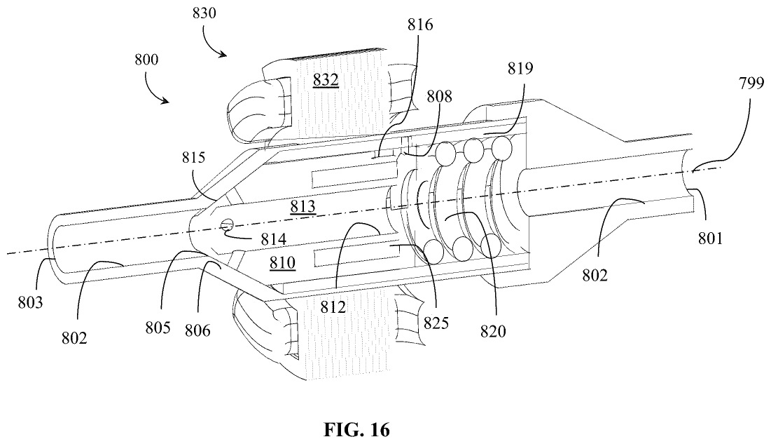

FIG. 14 depicts a selectively actuatable fluid flow control valve 800 having an internal bore 802 configured to convey fluid from an inlet 801 to an outlet 803. The valve 800 has a gate element 810 disposed in the bore 802. The gate element 810 is longitudinally positionable in the bore 802 from a first position (shown in FIG. 15), which allows fluid flow through the bore, to a second position (shown in FIG. 16), which restricts fluid flow through the bore 802. A bias member 820 is configured to urge the gate element 810 toward the second position, e.g., from the first position. For example, the bias member 820 can be configured as a resiliently compressible spring that, when compressed as in FIG. 15, urges the gate element 810 toward the first position. In some embodiments, the bias member 820 is coupled with the gate element to push (e.g., as the bias member expands) or pull (e.g., as the bias member retracts or collapses) the gate element toward the second position.

As FIG. 15 shows, the gate element 810 can define an open internal passageway (or bore) 812 open to the bore 802 defined by the valve. The internal passageway 812 can have a main channel 813 and a plurality of branches 814. As coolant flows from the inlet 801 through the internal bore 802, the coolant can enter the main channel 813 of the internal passageway 812 and split among the plurality of branches 814. The coolant that passes through the plurality of branches 814 when the gate element is in the first position (FIG. 15) recombines in a channel 804 between an outer wall 815 of the gate element 810 and an inner wall 805 of the valve housing 806.

When the gate element is in the second position (FIG. 16), the inner wall 805 of the valve housing and the outer wall 815 of the gate element 810 are in mating contact with each other. Such mating contact places the inner wall 805 of the valve housing over the apertures of the branches 814, closing off the branches and preventing coolant from passing through the valve housing. The bias member 820 urges the walls 805 and 815 together in compression, and fluid pressure within the coolant on the inlet side of the valve 800 further urges the walls 805 and 815 together in compression, thus preventing coolant from passing through the valve when the gate element is in the second position. The valve 800 can be reset to the open position (e.g., with the gate element 810 positioned as shown in FIG. 15) by a technician using an external magnet to pull the gate element 910 longitudinally toward the inlet 801 and by reversing the flow of current through the coil 832 (to reverse the torque applied to the gate element 810 by the electromagnetic field's interaction with the core 825).

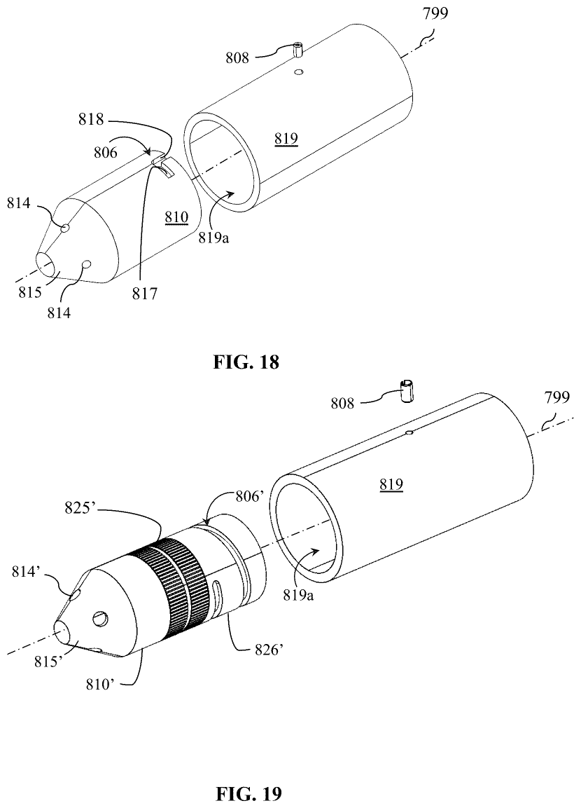

When the gate element 810 is in the first position, a retainer 808 can be configured to retain the gate element 810 in that position (e.g., the first position shown in FIG. 15) against a force applied (directly or indirectly) to the gate element 810 by the bias member 820. For example, in some embodiments, a retainer 808 comprises a dowel or a boss or other protrusion that engages a recessed region 816 of the gate element 810 (or a recessed region of another member that retains the gate element against urging of the bias member). The retainer 808 can extend radially inward from an internal sleeve 819 (FIG. 18) lining the bore 802. The gate element 810 can be longitudinally movable within the sleeve 819. A selectively actuatable magnet 830 or other actuator can cause the retainer (dowel or boss) to be withdrawn from the recess (e.g., a circumferential recess) as described above in connection with FIGS. 7 to 13. In other embodiments, a portion of the recess 816 extends in a longitudinal direction (e.g., relative to movement of the gate element in the bore between the first position and the second position, or parallel to the axis 799).

For example, the recess 816 can have a first portion 817 (FIG. 18) extending circumferentially (or transversely relative to the longitudinal direction) and a second portion 818 (FIG. 18) extending longitudinally, as with an L-shaped or a T-shaped recess. As shown in FIG. 19, the recess 806′ in other embodiments can extend in a longitudinally extending spiral around a circumference of the gate element 810′ (or of a segment 826′ of the gate element that retains the gate element against urging of the bias member). In such embodiments with a recess having a longitudinally extending portion, the gate element (or a segment thereof) can be made to rotate about the longitudinal access 799 (e.g., under magnetic forces between a transient electromagnetic field and a permanent magnet).

When the retainer 808 (e.g., the dowel or boss) aligns with the longitudinally extending portion of the recess 806, 806′, the gate element 810, 810′ (urged by the bias member) can be free to move toward the second position (FIG. 16). In some embodiments (e.g., with an L-shaped recess 806 as in FIG. 18 or a T-shaped recess), the gate element 810 can be released entirely to close the bore 802. In embodiments with a spiral recess 806′ (e.g., a thread), the gate element 810′ can be released longitudinally in correspondence with an angular displacement about the longitudinal axis 799 and a so-called “pitch”of the spiral recess.

In still other embodiments, the sleeve 819 defines a recess (e.g., an L-shaped recess, a T-shaped recess, or a spiral recess) and the retainer 808 (e.g., a dowel or a pin) extends radially outward from the outer surface of the gate element 810. As with embodiments described above, the retainer 808 in such an alternative arrangement can facilitate longitudinal movement of the gate element 810 as the gate element rotates and the retainer 808 passes into a longitudinally extending segment of a recess (despite that the recess in this alternative embodiment is defined by the sleeve 819 rather than the gate element 810).

To facilitate angular displacement of the recessed member (e.g., the gate element 810, 810′ or another member coupled with the gate element), the recessed member can be coupled with or can comprise one or more ferromagnetic core elements or a permanent magnet core 825 (FIGS. 15 and 16) or permanent magnet core 825′ (FIG. 19). The actuator 830 can include a coil 832 (sometimes referred to as a solenoid) to produce an electromagnetic field when an electrical current passes therethrough. The coil 832 can be configured to arrange poles of the electromagnetic field to be complementary with poles of a permanent magnet core 825, 825′ so that, on activation of the electromagnetic field, the permanent magnet core 825, 825′ imposes a torque on the gate element 810, 810′ to urge the gate element (and thus the segment thereof that defines the recess 806, 806′) in rotation about the axis 799 to align the longitudinal portion 818 of the recess with the retainer 808 (as with embodiments shown in FIG. 18) or to urge the gate element 810′ to move longitudinally as it rotates about the axis 799 (as with embodiments shown in FIG. 18).

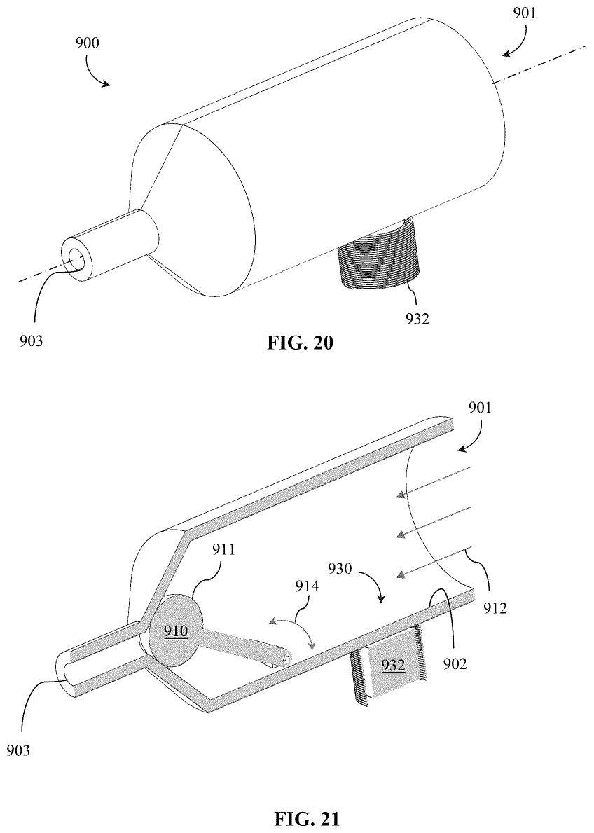

FIGS. 20 and 21 show another embodiment of a selectively actuatable fluid flow control valve 900 having an internal bore 902 configured to convey fluid from an inlet 901 to an outlet 903. The valve 900 has a gate element 910 disposed in the bore 902. The gate element 910 is longitudinally positionable in the bore 902 from a first position (indicated by arrow 930), which allows fluid flow through the bore 902, to a second position (shown in FIG. 21), which restricts fluid flow through the bore 902. However, unlike other embodiments described herein, the valve 900 does not need bias member to urge the gate element 910 toward the second position, e.g., from the first position. For example, the flow of coolant (indicated by arrows 912) can urge the gate element 910 into the second position shown in FIG. 21 when the head 911 of the gate element is magnetically released from the electromagnet 932. That being said, the head 911 of the gate element 910 can be a permanent magnet that, when positioned adjacent the region of the bore 902 adjacent the arrow 930, magnetically retains the head 911 against the wall of the bore 902 until an electrical current is supplied to the electromagnet 932. When such a current is supplied, a pole of the electromagnet 932 can repel (rather than attract) the magnetic pole of the magnetic head 911. In such an embodiment, the gate element 910 can swing through an arc (e.g., indicated by arrow 914) from the first position indicated by the arrow 930 to the second, closed position depicted in FIG. 21. In other embodiments, the head 911 of the gate element can be a ferromagnetic alloy and can be retained by the electromagnet 932 in the first position until a current through the electromagnet is terminated. In such an embodiment, hydrodynamic loading of the gate element 910 by the flow of coolant (indicated by arrows 912) can urge the gate element to swing toward the second position shown in FIG. 21, through the arc indicated by the arrow 914. The valve 900 can be reset to the open position (e.g., with the gate element positioned adjacent the region of the bore indicated by the arrow 930) by a technician using an external magnet to pull the head 911 of the gate element 910 longitudinally toward the inlet 901 when bolus of coolant is not present (or is under a sufficiently low pressure to allow the gate element 910 to release from the closed position shown in FIG. 21. The previous description is provided to enable a person skilled in the art to make or use the disclosed principles. Embodiments other than those described above in detail are contemplated based on the principles disclosed herein, together with any attendant changes in configurations of the respective apparatus or changes in order of method acts described herein, without departing from the spirit or scope of this disclosure. Various modifications to the examples described herein will be readily apparent to those skilled in the art.

By way of further example, other apparatus and methods for isolating one or more branches of a fluid circuit of a heat-transfer system are possible. For example, referring again to FIG. 6, a proportional or a zero-flow valve 502 can be positioned adjacent an inlet 150a to a branch (e.g., a heat-transfer element 110) of a fluid circuit in a heat-transfer system, and a check valve 501 can be positioned adjacent a corresponding outlet 140a. An actuator 503 of the type described herein can be operably coupled with the valve 502, as shown schematically in FIG. 6, and can cause the valve to open or close, entirely or partially, in response to an alarm or a command issued by a controller. On closing the valve 502, the check valve 501 can close to prevent a reversed flow (sometimes referred to in the art as “backflow”) of working fluid through the outlet 140a. The closure of the valves 501, 502 isolate the branch (e.g., the heat-transfer element 110a in FIGS. 1, 2, 3, 5, and 6 of U.S. patent application Ser. No. 13/559,340) from the remainder of the heat-transfer system.

In still other embodiments, a coupler 710 (FIG. 7) can have a sleeve that biases toward a normally open arrangement, e.g., that biases the sleeve toward the engagement/disengagement configuration. In such an embodiment, the outer collar 720 can be omitted and the pin 750 can extend through the sleeve of the coupler 710 (e.g., rather than through the outer collar 720) into a recess after the mating coupler has been inserted and the sleeve has been longitudinally translated into position to retain the mating coupler, e.g., into the retentional configuration of the coupler 710. In such an embodiment, withdrawal of the pin 750 as described above can cause the sleeve of the coupler 710 to automatically retract under force of the internal biasing member rather than under an external force (e.g., the outer collar 720). Moreover, such an arrangement can use a lighter spring than the spring 740 since only the force of friction between the coupler's body and its sleeve needs to be overcome by the internal biasing member. By contrast, the spring 740 shown in FIG. 7 must overcome not only such friction but also must overcome the force of the biasing member internal to the coupler 710, since that internal biasing member tends to urge the sleeve of the coupler into the coupler's retention configuration rather than into the engagement/disengagement configuration.

For conciseness and clarity, the foregoing describes isolation of a branch 110a of a heat-transfer system passing within a given server. Nonetheless, apparatus and methods just described can be suitable for isolating other branches of heat-transfer systems. For example, U.S. patent application Ser. No. 13/559,340 describes removing heat from a rack containing a plurality of servers by passing a facility coolant through a liquid-liquid heat exchanger. Depending on the plumbing arrangement of a given facility, a facility's coolant circuit can have a plurality of branches coupled to each other, for example, in parallel relative to a main conduit, similar to the arrangement of the plural heat-transfer elements 110a-n relative to each other and the manifold module 200 in FIGS. 5 and 6 in U.S. patent application Ser. No. 13/559,340. One or more such branches of a facility's coolant circuit can have a zero-flow or a proportional valve adjacent an inlet and a check valve positioned adjacent an outlet, and an electro-mechanical actuator can be operatively coupled to such zero-flow or proportional valve. The electro-mechanical actuator can be activated responsively to an alert or other command to close the corresponding valve, thereby isolating the corresponding branch from the facility's coolant circuit.

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper”surface can become a “lower”surface simply by turning the object over. Nevertheless, it is still the same surface and the object remains the same. As used herein, “and/or” means “and” or “or”, as well as “and” and “or.” Moreover, all patent and non-patent literature cited herein is hereby incorporated by reference in its entirety for all purposes.

And, those of ordinary skill in the art will appreciate that the exemplary embodiments disclosed herein can be adapted to various configurations and/or uses without departing from the disclosed principles. Applying the principles disclosed herein, it is possible to provide a wide variety of automatically couplable and decouplable fluid connections, and related methods and systems to provide a means for removing a portion of a liquid loop (e.g., a branch of a cooling loop) from a system, as when a leak occurs. For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of systems and techniques that can be devised using the various concepts described herein.

Moreover, nothing disclosed herein is intended to be dedicated to the public regardless of whether such disclosure is explicitly recited in the claims. No claim feature is to be construed under the provisions of 35 USC 112(f), unless the feature is expressly recited using the phrase “means for”or “step for”.

The appended claims are not intended to be limited to the embodiments shown herein, but are to be accorded the full scope consistent with the language of the claims, wherein reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, and more particularly but not exclusively in the claims appended hereto.

We currently claim:

1. An actuator for a quick-disconnect liquid coupler, comprising:
a collar defining an internal shoulder configured to urge against a longitudinal face of a radially extending sleeve of a quick-disconnect liquid coupler, the collar defining a radially extending bore longitudinally offset from the internal shoulder;
a bias member configured to urge the collar in a longitudinal direction;
a dowel extending through the radially extending bore defined by the collar, the dowel configured to extend radially inward of internal shoulder and into a recess defined by the quick-disconnect liquid coupler;
a tension member coupled with the dowel configured to radially retract the dowel within the collar when at least a threshold tensile load is applied to the tension member; and
an electro-mechanical actuator configured to selectively apply at least the threshold tensile load to the tension member.

2. The actuator according to claim 1, further comprising a chassis stud extending from a proximal end to a distal end, the chassis stud having a flange at the distal end, wherein the bias member engages the flange to urge the collar in a longitudinal direction.

3. The actuator according to claim 2, wherein the collar has a proximal flange longitudinally positioned between the flange at the distal end of the chassis stud and the proximal end of the chassis stud, wherein the bias member comprises a resiliently deformable coil spring extending around the chassis stud and being longitudinally captured between the flange at the distal end of the chassis stud and the proximal flange of the collar.

4. The actuator according to claim 3, wherein the resiliently deformable coil spring is in a state of compression when the internal shoulder of the collar urges against the longitudinal face of the radially extending sleeve of the quick-disconnect liquid coupler and the bore through the collar so aligns with the recess defined by the quick-disconnect liquid coupler that the dowel can extend through the bore and into the recess.

5. The actuator according to claim 1, further comprising a chassis stud extending from a proximal end to a distal end, wherein the bias member comprises a resiliently deformable coil spring having a first end captured by the collar and an opposed second end captured by the chassis stud, wherein the resiliently deformable coil spring is in a state of tension when the internal shoulder of the collar urges against the longitudinal face of the radially extending sleeve of the quick-disconnect liquid coupler and the bore through the collar so aligns with the recess defined by the quick-disconnect liquid coupler that the dowel can extend through the bore and into the recess.

6. The actuator according to claim 1, wherein the collar is a first collar, the bias member is a first bias member, and the dowel is a first dowel, the actuator further comprising:
a second collar defining an internal shoulder configured to urge against a longitudinal face of a radially extending sleeve of a quick-disconnect liquid coupler, the second collar defining a radially extending bore longitudinally offset from the internal shoulder;
a second bias member configured to urge the second collar in a longitudinal direction;
a second dowel extending through the radially extending bore defined by the second collar, the second dowel configured to extend radially inward of internal shoulder defined by the second collar.

7. The actuator according to claim 6, wherein the tension member is further coupled with the second dowel and configured to radially retract the second dowel within the collar when at least the threshold tensile load is applied to the tension member.

8. The actuator according to claim 6, wherein the tension member is a first tension member, the actuator further comprising a second tension member coupled with the second dowel and configured to radially retract the second dowel within the collar when at least a second threshold tensile load is applied to the second tension member.

9. The actuator according to claim 9, wherein the electro-mechanical actuator is further configured to selectively apply at least the second threshold tensile load to the second tension member.

10. An electro-mechanically actuatable valve, comprising:
a valve body defining an internal bore extending from an inlet to an outlet and configured to convey fluid therethrough;
a gate element longitudinally positionable between a first longitudinal position and a second longitudinal position, wherein the gate element permits fluid to pass through the valve body when the gate element is in the first longitudinal position and wherein the gate element blocks fluid flow through the valve body when the gate element is in the second longitudinal position;
an armature and a coil configured to expose the armature to an electromagnetic field when an electrical current passes through the coil, wherein the armature is so coupled with the gate element as to retain the gate element in the first position or to urge the gate element to move when the electrical current passes through the coil.

11. The electro-mechanically actuatable valve according to claim 10, further comprising a retainer extending radially inward of the valve body, wherein the gate element has a portion defining a recess and wherein the retainer is positioned within the recess.

12. The electro-mechanically actuatable valve according to claim 11, wherein the recess has a circumferentially extending segment and a longitudinally extending segment, wherein the armature is so coupled with the gate element as to urge the gate element to rotate about a longitudinal axis within the valve body when the electrical current passes through the coil.

13. The electro-mechanically actuatable valve according to claim 12, wherein the longitudinally extending segment of the recess aligns with the retainer when the gate element rotates through a threshold angular displacement.

14. The electro-mechanically actuatable valve according to claim 13, wherein the armature and the coil are so configured as to urge the gate element to rotate through the threshold angular displacement when the electrical current passes through the coil.

15. The electro-mechanically actuatable valve according to claim 11, wherein the recess extends in longitudinally extending circumferential spiral around the gate element.

16. The electro-mechanically actuatable valve according to claim 15, wherein the armature and the coil are so configured as to urge the gate element to rotate through a threshold angular displacement when the electrical current passes through the coil.

17. The electro-mechanically actuatable valve according to claim 16, wherein the recessed longitudinally extending circumferential spiral defines a pitch, wherein the pitch and the threshold angular displacement so correspond with each other that the gate element moves from the first position to the second position when the gate element rotates through the threshold angular displacement.

18. The electro-mechanically actuatable valve according to claim 10, wherein the gate element has a head and an arm, wherein the arm couples the head of the gate element with the internal bore, wherein the head of the gate element is movable throughout at least one degree-of-freedom between the first position and the second position.

19. The electro-mechanically actuatable valve according to claim 18, wherein the head of the gate element comprises the armature, wherein the armature is configured retain the head of the gate element in the first position when the electrical current passes through the coil.

20. The electro-mechanically actuatable valve according to claim 19, wherein the head of the gate element is configured to move from the first position to the second position and block fluid flow through the valve body when the electrical current through the coil ceases.
